(19) United States
(12) Patent Application Publication
(10) Pub. No.: US 2024/0057399 A1
(43) Pub. Date: Feb. 15, 2024

(54) DISPLAY PANEL AND ELECTRONIC DEVICE

(71) Applicant: Wuhan China Star Optoelectronics Semiconductor Display Technology Co., Ltd., Wuhan, Hubei (CN)

(72) Inventor: Guoqiang YANG, Wuhan, Hubei (CN)

(21) Appl. No.: 17/594,547

(22) PCT Filed: Sep. 1, 2021
(86) PCT No.: PCT/CN2021/115964

§ 371 Date: Oct. 21, 2021

(30) Foreign Application Priority Data
Aug. 20, 2021 (CN) 202110958891.1

(51) Int. Cl. H10K 59/124

(52) U.S. Cl. CPC H10K 59/124

(57) ABSTRACT

A display panel and an electronic device are disclosed. The display panel includes a display area and a bending area located in one side of the display area. A first via hole is defined in a second inorganic layer of the display panel in the bending area. The first via hole penetrates the second inorganic layer and part of the first inorganic layer, so that an area of the first inorganic layer corresponding to the first via hole retain a certain thickness of whole film layer to protect a first transparent substrate, thereby solving the problem of local mura occurring in the position near the bending area in the existing display panel.

### FIELD OF INVENTION

The present disclosure relates to the field of display technology, and more particularly, to a display panel and an electronic device.

### BACKGROUND OF INVENTION

With the development of display technology, the market demand for display panels with high screen-to-body ratios is becoming more and more urgent. The display panel is developing towards full screen, thinness, and light weight, and the realization of full screens is inseparable from under-screen camera technology. As the name suggests, the under-screen camera technology means to place a front camera under a display panel. The placement of the front camera under the display panel is not difficult, but the difficulty is how to solve the problem of light transmittance in an area of the under-screen camera. In order to effectively enhance the transmittance of the area of the under-screen camera, substrate material of the display panel may be selected from clear polyimide (CPI). However, the clear polyimide has the problems of large thermal stress, water absorption, and large thermal expansion coefficient, which may lead to the occurrence of local mura in the position near a bending area of the display panel.

Therefore, there is a requirement for solving a problem of local mura occurring in the position near the bending area of the existing display panel.

### SUMMARY OF INVENTION

### Technical Problem

A display panel and an electronic device are disclosed in the present disclosure to solve the technical problem of local mura occurring in the position near the bending area of the existing display panel.

### Technical Solutions

In order to solve the aforementioned problem, the technical solutions are disclosed in embodiments of the present disclosure as below:

A display panel is disclosed in the embodiments of the present disclosure, wherein the display panel includes a display area and a bending area located in one side of the display area, wherein the display panel further includes:
a first transparent substrate;
a first inorganic layer located on one side of the first transparent substrate;
a semiconductor layer disposed on one side of the first inorganic layer away from the first transparent substrate; and
a second inorganic layer covering on the semiconductor layer and the first inorganic layer;
wherein a first via hole is defined in the second inorganic layer in the bending area, and the first via hole penetrates the second inorganic layer and part of the first inorganic layer.

In the display panel disclosed in the embodiments of the present disclosure, the first inorganic layer includes at least one silicon oxide layer and at least one silicon nitride layer.

In the display panel disclosed in the embodiments of the present disclosure, the first inorganic layer includes a first silicon nitride layer covering on the first transparent substrate and a first silicon oxide layer covering one side of the first silicon nitride layer away from the first transparent substrate, and the first via hole penetrates part or all of the first silicon oxide layer to expose the first silicon nitride layer.

In the display panel disclosed in the embodiments of the present disclosure, the first inorganic layer further includes a second silicon nitride layer covering one side of the first silicon oxide layer away from the first silicon nitride layer, and the first via hole further penetrates the second silicon nitride layer.

In the display panel disclosed in the embodiments of the present disclosure, the first inorganic layer includes a first silicon oxide layer, a first silicon nitride layer, a second silicon oxide layer, and a second silicon nitride layer which are stacked on the first transparent substrate in order, and the first via hole penetrates the second silicon nitride layer and the second silicon oxide layer to expose the first silicon nitride layer.

In the display panel disclosed in the embodiments of the present disclosure, a thickness of the first silicon oxide layer is smaller than a thickness of the second silicon oxide layer.

In the display panel disclosed in the embodiments of the present disclosure, the first transparent substrate is provided with a plurality of first protrusions in an area corresponding to the first via hole.

In the display panel disclosed in the embodiments of the present disclosure, a surface of the first inorganic layer exposed by the first via hole is provided with a plurality of second protrusions.

In the display panel disclosed in the embodiments of the present disclosure, a thickness of the first inorganic layer exposed by the first via hole ranges from 1000 angstroms to 5000 angstroms.

In the display panel disclosed in the embodiments of the present disclosure, the display panel further includes a function area disposed adjacent to the display area and a first thin film transistor and a second thin film transistor which are disposed in the display area, and the first thin film transistor is disposed close to the function area, wherein the display panel further includes:
an electrically conductive electrode layer disposed on one side of the first thin film transistor and the second thin film transistor away from the first transparent substrate, wherein a first pixel electrode is formed in the function area, a second pixel electrode is formed in the display area, the first pixel electrode is connected with the first thin film transistor, and the second pixel electrode is connected with the second thin film transistor.

In the display panel disclosed in the embodiments of the present disclosure, a bridge layer is further disposed between the first thin film transistor and the electrically conductive electrode layer, the bridge layer forms a first bridge electrode in the function area and a second bridge electrode in the display area, the first pixel electrode is connected with the first thin film transistor through the first bridge electrode, and the second pixel electrode is connected with the second thin film transistor through the second bridge electrode.

In the display panel disclosed in the embodiments of the present disclosure, the second inorganic layer includes a gate insulating layer and an interlayer insulating layer which are stacked in order, and the gate insulating layer is disposed to face the semiconductor layer, the semiconductor layer forms a channel region of the first thin film transistor and a channel region of the second thin film transistor and a source region and a drain region located on both sides of the channel region in the display area, and the gate insulating layer covers on the semiconductor layer and the first inorganic layer, wherein the display panel further includes:
a gate layer disposed on the gate insulating layer, wherein the gate layer forms a gate of the first thin film transistor and a gate of the second thin film transistor in the display area, and forms a first signal transfer line in the bending area, wherein the interlayer insulating layer covers on the gate layer and the gate insulating layer, the interlayer insulating layer is patterned to form the first via hole, and to form a second via hole in the display area;
a first source/drain layer disposed on the interlayer insulating layer, wherein the first source/drain layer forms a first source and a first drain of the first thin film transistor and a first source and a first drain of the second thin film transistor in the display area, and forms a second signal transfer line in the bending area;
a first planarization layer covering on the first source/drain layer and the interlayer insulating layer, and filling the first via hole;
a second source/drain layer disposed on the first planarization layer, wherein the second source/drain layer forms a second source of the first thin film transistor and a second source of the second thin film transistor in the display area, and forms a plurality of binding lines in the bending area;
a second planarization layer covering on the second source/drain layer and the first planarization layer, wherein the bridge layer is disposed on the second planarization layer;
a third planarization layer covering on the bridge layer and the second planarization layer, wherein the electrically conductive electrode layer is disposed on the third planarization layer;
wherein the gate is disposed corresponding to the channel region, the first source is connected with the source region, the first drain is connected with the drain region, the second source is connected with the first drain, the first bridge electrode and the second bridge electrode are respectively connected with the corresponding second source, the first signal transfer line is connected with the second signal transfer line, and the binding lines are connected with the second signal transfer line.

An electronic device is also disclosed in the embodiments of the present disclosure, wherein the electronic device includes the display panel in one of the aforementioned embodiments.

### Beneficial Effect

In the display panel and the electronic device disclosed in the present disclosure, the display panel includes the first inorganic layer, the second inorganic layer, and the second inorganic layer which are stacked on the first transparent substrate. A first via hole is defined in the second inorganic layer in the bending area of the display panel. The first via hole penetrates the second inorganic layer and part of the first inorganic layer, so that an area of the first inorganic layer corresponding to the first via hole retains a certain thickness of whole film layer to protect the first transparent substrate and avoids the influences of water vapor and the etching process of the first via hole on the first transparent substrate. Accordingly, the problem that mura occurs near the bending area due to the exposed first transparent substrate is avoided, and thus the problem of local mura occurring in the position near the bending area in the existing display panel is solved.

### DESCRIPTION OF DRAWINGS

In order to describe the technical solutions in the embodiments of the present disclosure or in the prior art more clearly, the following briefly introduces the accompanying drawings required for describing the embodiments or the prior art. Apparently, the accompanying drawings in the following description show merely some embodiments of the present disclosure, and a person of ordinary skill in the art may still derive other drawings from these accompanying drawings without creative efforts.

FIG. 1 is a top view of a schematic structural diagram of a display panel disclosed in the embodiments of the present disclosure.

FIG. 2 is a first section view of a schematic structural diagram of a display panel disclosed in the embodiments of the present disclosure.

FIG. 3 is a partial section view of the schematic structural diagram of the display panel in FIG. 2.

FIG. 4 and FIG. 5 are detailed views of a first via disclosed in the embodiments of the present disclosure.

FIG. 6 is a second section view of a schematic diagram of a display panel disclosed in the embodiments of the present disclosure.

FIG. 7 is a third section view of a schematic diagram of a display panel disclosed in the embodiments of the present disclosure.

FIG. 8 is a fourth section view of a schematic diagram of a display panel disclosed in the embodiments of the present disclosure.

FIG. 9 is a partial section view of the schematic structural diagram of the display panel in FIG. 8.

FIG. 10 is a diagram of a relationship between the retained thickness of the first inorganic layer and the bending stress in the bending area obtained by simulation according to the embodiments of the present disclosure.

FIG. 11 is a fifth section view of a schematic diagram of a display panel disclosed in the embodiments of the present disclosure.

FIG. 12 is a sixth section view of a schematic diagram of a display panel disclosed in the embodiments of the present disclosure.

FIG. 13 is a partial-detailed view of a display panel disclosed in the embodiments of the present disclosure.

### DETAILED DESCRIPTION OF PREFERRED EMBODIMENTS

The description of each embodiment below refers to respective accompanying drawing(s), so as to illustrate exemplarily specific embodiments of the present disclosure that may be practiced. Directional terms mentioned in the present disclosure, such as “upper”, “lower”, “front”, “back”, “left”, “right”, “inner”, “outer”, “side”, etc., are only directions by referring to the accompanying drawings, and thus the directional terms are used to describe and understand the present disclosure, but the present disclosure is not limited thereto. In the drawings, structurally similar units are labeled by the same reference numerals. In the drawings, for understanding and ease of description, the thickness of some layers and areas is exaggerated. That is, the size and thickness of each component shown in the drawings are arbitrarily shown, but the present disclosure is not limited thereto.

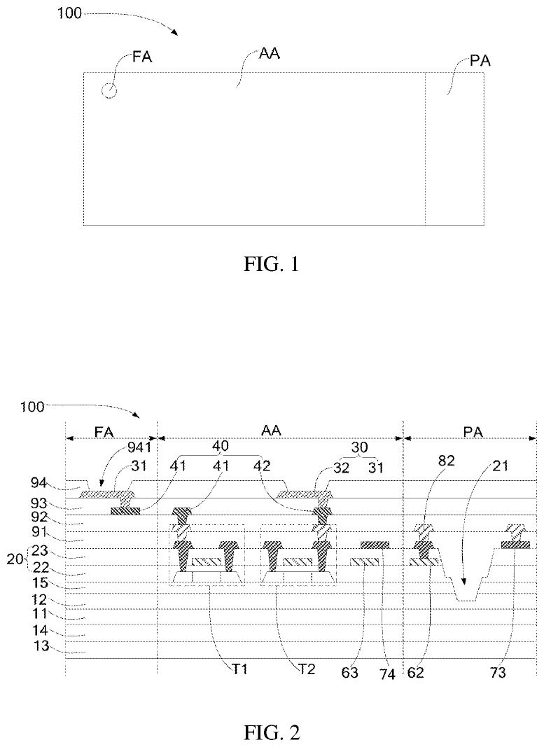

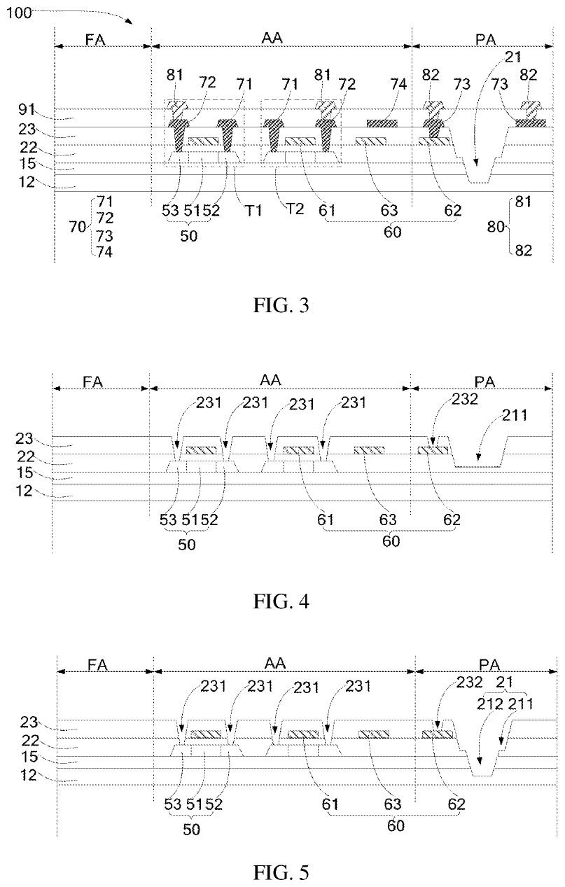

References are made to FIG. 1 to FIG. 5. FIG. 1 is a top view of a schematic structural diagram of a display panel disclosed in the embodiments of the present disclosure. FIG. 2 is a first section view of a schematic structural diagram of a display panel disclosed in the embodiments of the present disclosure. FIG. 3 is a partial section view of the schematic structural diagram of the display panel in FIG. 2. FIG. 4 and FIG. 5 are detailed views of a first via disclosed in the embodiments of the present disclosure. The display panel 100 includes a display area AA, a function area FA arranged adjacent to the display area AA, and a bending area PA located in one side of the display area AA. The bending area PA can be bent to a back of the display panel 100 to achieve narrow bezel or no bezel. The function area FA may be located at any position in the display area AA. The function area FA can be configured for realizing various functions such as under-screen fingerprint recognition, face recognition, under-screen camera, and can also be configured for displaying, thereby achieving a real full screen.

Specifically, the display panel 100 further includes a first transparent substrate 11, a first inorganic layer 12, a semiconductor layer 50, and a second inorganic layer 20. The first inorganic layer 12 is located on one side of the first transparent substrate 11, and the semiconductor layer 50 is disposed on one side of the first inorganic layer 12 away from the first transparent substrate 11. The second inorganic layer 20 covers on the semiconductor layer 50 and the first inorganic layer 12. A first via hole 21 is defined in the second inorganic layer 20 in the bending area PA, and the first via hole 21 penetrates through the second inorganic layer 20 and part of the first inorganic layer 12.

The material of the first transparent substrate 11 includes clear polyimide (CPI), and the like. The clear polyimide has higher transmittance than yellow polyimide (YPI). Therefore, the use of the clear polyimide can improve the light transmittance of the function area FA. However, the use of the clear polyimide may also lead to many undesirable results. For example, due to high water vapor transmittance of the clear polyimide, the water vapor may enter into the first transparent substrate 11 when manufacturing the first via hole 21. For another example, large thermal stress of the clear polyimide may cause the stress in the bending area PA to expand to the display area AA, thereby resulting in the occurrence of mura in the display area AA near the bending area PA.

In the present disclosure, the first via hole 21 penetrates part of the first inorganic layer 12. That is, the first via hole 21 penetrates the part of the first inorganic layer 12 between the semiconductor layer 50 and the first transparent substrate 11, so that the first inorganic layer 12 with a certain thickness on the first transparent substrate 11 corresponding to the first via hole 21 is retained. That is, the first via hole 21 exposes the first inorganic layer 12 with a certain thickness. The material of the first inorganic layer 12 includes one of inorganic materials such as silicon oxide (SiOx) and silicon nitride (SiNx). In the present embodiment, the first inorganic layer 12 may be formed of single-layer silicon nitride. Silicon nitride has excellent ability to block water vapor. Therefore, the first inorganic layer 12 with a certain thickness on the first transparent substrate 11 can protect the first transparent substrate 11, thereby avoiding mura caused by the first transparent substrate 11 used of the clear polyimide.

The film layer structure of each area on the display panel 100 may be described in detail as below.

The display panel 100 includes the first transparent substrate 11, the second inorganic layer 20 disposed on one side of the first transparent substrate 11, a first thin film transistor T1 and a second thin film transistor T2 disposed in the second inorganic layer 20, and an electrically conductive electrode layer 30 disposed on one side of the first thin film transistor T1 and the second thin film transistor T2 away from the first transparent substrate 11.

Optionally, the display panel 100 further includes a third inorganic layer 14 and a second transparent substrate 13. The third inorganic layer 14 is located on one side of the first transparent substrate 11 away from the first inorganic layer 12, and the second transparent substrate 13 is located on one side of the third inorganic layer 14 away from the first transparent substrate 11. The material of the second transparent substrate 13 is equal to the material of the first transparent substrate 11, and the material of the third inorganic layer 14 is equal to the material of the first inorganic layer 12, thereby achieving excellent barrier effect against water vapor.

Optionally, both the first transparent substrate 11 and the second transparent substrate 13 may be formed by wet film coating, preforming high vacuum dry (HVCD) to remove the solvent after the wet film coating is completed, and then curing the films. High vacuum dry can be used under the conditions of 40° C. to 80° C. and pressures of 0-10 pa for 250 seconds to 550 seconds. Curing can be carried out at a temperature of 400° C. to 450° C. for 30 minutes.

The second inorganic layer 20 includes a gate insulating layer 22 and an interlayer insulating layer 23 which are stacked in order, and the gate insulating layer 22 is disposed to face the semiconductor layer 50.

The display panel 100 is provided with the first thin film transistor T1 and the second thin film transistor T2 in the second inorganic layer 20 of the display area AA. The first thin film transistor T1 and the second thin film transistor T2 are disposed on the same layer, and the first thin film transistor T1 is disposed close to the function area FA.

The electrically conductive electrode layer 30 is disposed on one side of the first thin film transistor T1 and the second thin film transistor T2 away from the first transparent substrate 11. The electrically conductive electrode layer 30 forms a first pixel electrode 31 in the function area FA and a second pixel electrode 32 in the display area AA. The first pixel electrode 31 is connected with the first thin film transistor T1, and the second pixel electrode 32 is connected with the second thin film transistor T2.

Optionally, a bridge layer 40 is further disposed between the first thin film transistor T1 and the electrically conductive electrode layer 30. The bridge layer 40 forms a first bridge electrode 41 in the function area FA and a second bridge electrode 42 in the display area AA. The first bridge electrode 41 extends from the function area FA to the display area AA and is connected to the first thin film transistor T1. The first pixel electrode 31 is connected to the first thin film transistor T1 through the first bridge electrode 41, and the second pixel electrode 32 is connected to the second thin film transistor T2 through the second bridge electrode 42.

Specifically, the display panel 100 further includes a gate layer 60, a first source/drain layer 70, a second source/drain layer 80, and a multilayer planarization layer. The semiconductor layer 50 is disposed on the first inorganic layer 12. Optionally, a buffer layer 15 may be further disposed between the first inorganic layer 12 and the semiconductor layer 50, and the semiconductor layer 50 is disposed on the buffer layer 15. The material of the buffer layer 15 may include inorganic material such as silicon oxide (SiOx), silicon nitride (SiNx), silicon oxynitride (SiON). The buffer layer 15 can prevent unexpected impurities or pollutants (e.g., moisture, oxygen, etc.) from diffusing from the first transparent substrate 11 to devices that may be damaged by these impurities or pollutants, and can also provide a flat top surface.

The semiconductor layer 50 forms a channel region 51 of the first thin film transistor T1, a channel region 51 of the second thin film transistor T2, and a source region 52 and drain region 53 on both sides of the channel region 51 in the display region AA. The gate insulating layer 22 covers on the semiconductor layer 50 and the first inorganic layer 12. Certainly, if the display surface 100 further includes the buffer layer 15, the gate insulating layer 22 covers on the semiconductor layer 50 and the buffer layer 15.

The gate layer 60 is disposed on the gate insulating layer 22. The gate layer 60 forms a gate 61 of the first thin film transistor T1 and a gate 61 of the second thin film transistor T2 in the display area AA, and the gates 61 are disposed corresponding to the channel regions 51. Certainly, the gate layer 60 can further form signal lines such as gate scanning lines 63 in the display area AA. The gate layer 60 also forms a first signal transfer line 62 in the bending area PA, which is connected with the gate scanning line 63 and is configured to provide scanning signals to the gate 61 to control the cut off of the corresponding first thin film transistor T1 and the second thin film transistor T2.

The interlayer insulating layer 23 covers on the gate layer 60 and the gate insulating layer 22, and the interlayer insulating layer 23 is patterned to form the first via hole 21 in the bending area PA and the second via hole 231 in the display area AA.

The first via hole 21 includes a first sub-hole 211 and a second sub-hole 212, and an opening of the first sub-hole 211 is larger than an opening of the second sub-hole 212. The first sub-hole 211 and the second via 231 are formed under the same process conditions. The first sub-hole 211 and the second via hole 231 both penetrate the interlayer insulating layer 23 and part of the gate insulating layer 22. The second via hole 231 exposes the corresponding source region 52 and the drain region 53, as shown in FIG. 4. Certainly, while forming the first sub-hole 211 and the second via 231, a third via 232 is further formed in the bending area PA, and the third via 232 also penetrates through the interlayer insulating layer 23 and part of the gate insulating layer 22 to expose the first signal transfer line 62.

After the first sub-hole 211 is formed, the film layer on the bottom of the first sub-hole 211 is etched by dry etching to form the second sub-hole 212. The second sub-hole 212 penetrates through the gate insulating layer 22, the buffer layer 15, and part of the first inorganic layer 12 on the bottom of the first sub-hole 211, as shown in FIG. 5. When forming the second sub-hole 212, by controlling the time of dry etching, the first inorganic layer 12 with a certain thickness is retained on the first transparent substrate 11 corresponding to the area of the first via hole 21 to protect the first transparent substrate 11. Optionally, the thickness of the retained first inorganic layer 12 ranges from 1000 angstroms to 5000 angstroms to ensure excellent barrier effect against water vapor.

The first source/drain layer 70 is disposed on the interlayer insulating layer 23. The first source/drain layer 70 forms first sources 71 and first drains 72 of the first thin film transistor T1 and the second thin film transistor T2 in the display area AA. The first source 71 and the first drain 72 are respectively connected with the corresponding source region 52 and the drain region 53 through different second via holes 231. Certainly, the first source/drain layer 70 also forms signal lines such as data lines 74 in the display area AA.

The first source/drain layer 70 forms a second signal transfer line 73 in the bending area PA, and a part of the second signal transfer line 73 is connected with the corresponding data line 74 to provide data signals to the corresponding first thin film transistor T1 and the second thin film transistor T2. Another part of the second signal transfer line 73 is connected with the corresponding first signal transfer line 62 through the third via hole 232.

The first planarization layer 91 covers on the first source/drain layer 70 and the interlayer insulating layer 23, and fills the first via hole 21. The first planarization layer 91 is an organic material. By filling the first planarization layer 91 in the first via hole 21, the bending performance in the bending area PA may be improved, and the process of filling other organic materials in the first via hole 21 may be simplified.

It can be understood that when manufacturing the first planarization layer 91 formed of organic material, the organic material solution is usually manufactured on other film layers by the process such as coating or inkjet printing and cured into a film, and the first inorganic layer 12 retained on the bottom of the first via hole 21 can effectively prevent the organic material solution from entering the first transparent substrate 11 to generate free charges in the first transparent substrate 11. Moreover, in the photolithography process for manufacturing the first via hole 21, there is usually a process of stripping the photoresist. The first inorganic layer 12 retained on the bottom of the first via hole 21 can also prevent the stripping liquid for stripping the photoresist from entering into the first transparent substrate 11. If the stripping liquid enters the first transparent substrate 11, the stripping liquid may permeate into the contact interface between the first transparent substrate 11 and other substrates due to high water vapor transmittance of the first transparent substrate 11, which results in the decrease of the adhesion between the first transparent substrate 11 and the other substrates. Moreover, since the thermal stress of the first transparent substrate 11 is large, the stress in the area of the first via hole 21 tends to expand to the area with low adhesion and extend to the display area AA close to the bending area PA, which leads to the variation of the grain boundary of the semiconductor device of the thin film transistor in said area to further change the characteristic of the thin film transistor, and thus mura occurs in said area. Therefore, the first inorganic layer 12 retained on the bottom of the first via hole 21 can further solve the problem of the occurrence of mura in the display area AA close to the bending area PA.

The second source/drain layer 80 is disposed on the first planarization layer 91. The second source/drain layer 80 forms the second sources 81 of the first thin film transistor T1 and the second thin film transistor T2 in the display area AA, and the second sources 81 are connected with the first drains 72 through the via holes of the first planarization layer 91. The second source/drain layer 80 further forms a plurality of binding lines 82 in the bending area PA, and the binding line 82 is connected with the second signal transfer line 73 through the via hole of the first planarization layer 91.

The second planarization layer 92 covers on the second source/drain layer 80 and the first planarization layer 91. The bridge layer 40 is disposed on the second planarization layer 92, and the bridge layer 40 is a transparent electrically conductive electrode layer, which enhances the transmittance of the function area FA. The material of the bridge layer 40 includes transparent conductive oxide (TCO) material such as ITO, IZO, ZnO, or In2O3. The first bridge electrode 41 and the second bridge electrode 42 formed from the bridge layer 40 are connected with the corresponding second sources 81 through different via holes of the second planarization layer 92.

The third planarization layer 93 covers on the bridge layer 40 and the second planarization layer 92. The electrically conductive electrode layer 30 is disposed on the third planarization layer 93. The first pixel electrode 31 and the second pixel electrode 32 formed from the electrically conductive electrode layer 30 are respectively connected with the corresponding first bridge electrode 41 and the second bridge electrode 42 through different via holes of the third planarization layer 93. By disposing the first thin film transistor T1 in the display area AA close to the function area FA which is connecting with the first pixel electrode 31 through the first bridge electrode 41, the transmittance of the function area FA can further be improved on the premise of meeting the display function of the function area FA. Optionally, the material of the electrically conductive electrode layer 30 may be the same as the material of the bridge layer 40. Alternatively, the material of the electrically conductive electrode layer 30 may also be Ag, Mg, Al, Pt, Pd, Au, Ni, Nd, Ir, Cr, and other electrode materials.

Certainly, the display panel 100 further includes a pixel definition layer 94 disposed on the electrically conductive electrode layer 30 and the third planarization layer 93. The pixel definition layer 94 is provided with pixel openings 941 corresponding to the first pixel electrode 31 and the second pixel electrode 32 to expose the first pixel electrode 31 and the second pixel electrode 32.

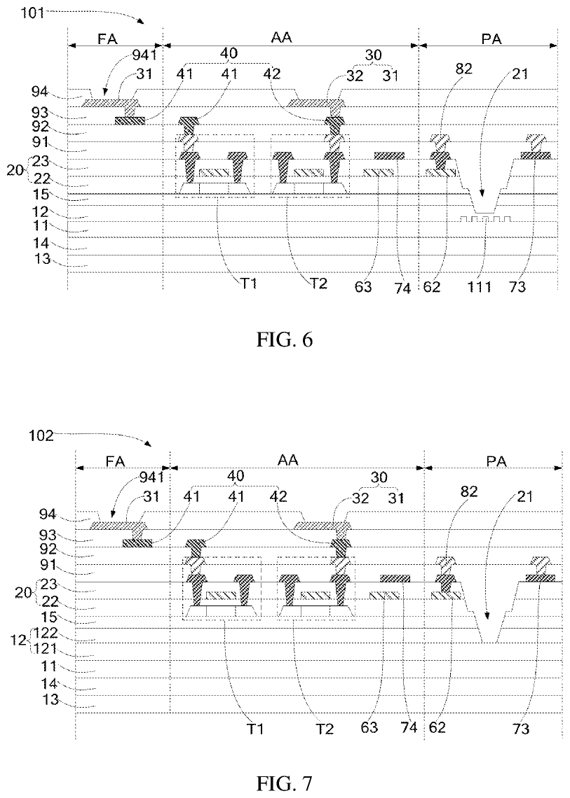

In one embodiment, reference is made to FIG. 6. FIG. 6 is a second section view of a schematic structural diagram of the display panel disclosed in the embodiments of the present disclosure. Different from the above embodiments, in the display panel 101 of the present embodiment, the first transparent substrate 11 is provided with a plurality of first protrusions 111 in an area corresponding to the first via hole 21. The first protrusion 111 can extend the diffusion and infiltration path of water vapor and reduce the stress expansion caused by the thermal stress of the first transparent substrate 11 in the area of the first via hole 21, so as to achieve the purpose of releasing water vapor and stress. In this way, the problem of the occurrence of mura in the display area AA close to the bending area PA may be further improved. Optionally, the cross-sectional shape of the first protrusion 111 includes square, trapezoid, triangle, etc. The other descriptions may refer to the above embodiments, and are not redundantly repeated herein.

In one embodiment, reference is made to FIG. 7. FIG. 7 is a third section view of a schematic structural diagram of the display panel disclosed in the embodiments of the present disclosure. Different from the above embodiments, in the display panel 102 of the present embodiment, the first inorganic layer 12 adopts a laminated structure to achieve excellent barrier effect against water vapor. The first inorganic layer 12 includes at least one silicon oxide layer and at least one silicon nitride layer. Specifically, the first inorganic layer 12 includes a first silicon nitride layer 121 covering on the first transparent substrate 11 and a first silicon oxide layer 122 covering one side of the first silicon nitride layer 121 away from the first transparent substrate 11. The first via hole 21 penetrates part or all of the first silicon oxide layer 122 to expose the first silicon nitride layer 121. Optionally, the thickness of the first inorganic layer 12 exposed by the first via hole 21 ranges from 1000 angstroms to 5000 angstroms. That is, the thickness of the first silicon nitride layer 121 retained in the area of the first via hole 21 ranges from 1000 angstroms to 5000 angstroms. The other descriptions may refer to the above embodiments, and are not redundantly repeated herein.

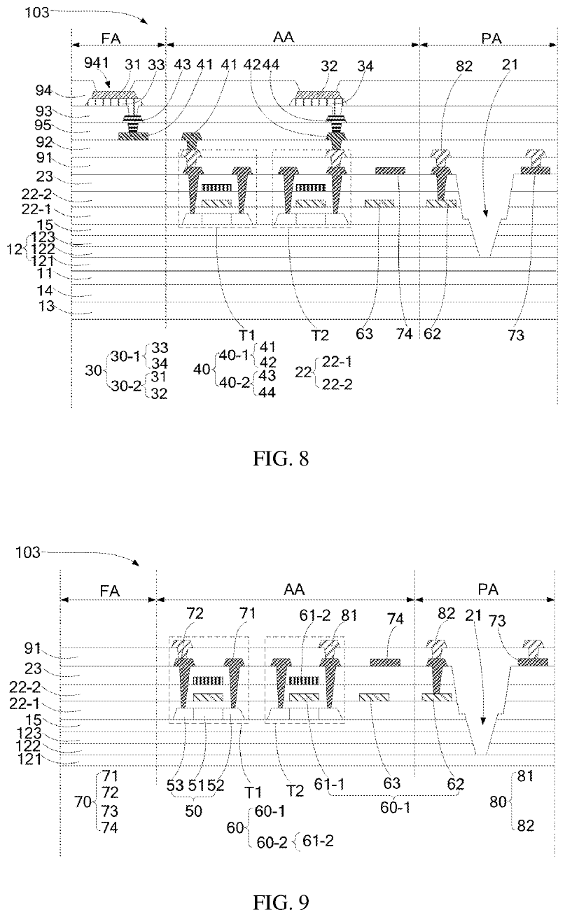

In one embodiment, references are made to FIG. 8 and FIG. 9. FIG. 8 is a fourth section view of a schematic structural diagram of the display panel disclosed in the embodiments of the present disclosure. FIG. 9 is a partial section view of the schematic structural diagram of the display panel in FIG. 8. Different from the above embodiments, in the display panel 103 of the present embodiment, the first inorganic layer 12 further includes a second silicon nitride layer 123 covering one side of the first silicon oxide layer 122 away from the first silicon nitride layer 121, and the first via hole 21 further penetrates the second silicon nitride layer 123. That is, the first via hole 21 penetrates the second silicon nitride layer 123 and part or all of the first silicon oxide layer 122 of the first inorganic layer 12.

Optionally, the thickness of the first silicon nitride layer 121 ranges from 500 angstroms to 2000 angstroms. The thickness of the first silicon oxide layer 122 ranges from 2000 angstroms to 6000 angstroms. The thickness of the second silicon nitride layer 123 ranges from 500 angstroms to 2000 angstroms. The thickness of the first inorganic layer 12 exposed by the first via hole 21 ranges from 1000 angstroms to 5000 angstroms. By disposing the first inorganic layer 12 with laminated structure and retaining the first inorganic layer 12 with a thickness of 1000 angstroms to 5000 angstroms in the area of the first via hole 21, it not only achieves the function of blocking water vapor to protect the first transparent substrate 11, but also facilitates adjusting the stress center layer in the bending area PA to avoid increasing the risk of crack of the binding lines 82 in the bending area PA.

It should be noted that in order to reduce the risk of crack of the binding lines 82 in the bending area PA, the film layer for disposing the binding lines 82 is usually adjusted as the stress center layer in the bending area PA. The first inorganic layer 12 with a certain thickness is retained in the area of the first via hole 21, which may cause the stress center layer in the bending area PA to move down, thereby increasing the bending stress on the binding lines 82 in the bending area PA. Moreover, with the increase of the retained thickness of the first inorganic layer 12, the bending stress on the binding lines 82 in the bending area PA may also increase, as shown in FIG. 10. FIG. 10 is a diagram of a relationship between the retained thickness of the first inorganic layer and the bending stress in the bending area obtained by simulation according to the embodiments of the present disclosure. In FIG. 10, the abscissa represents the retained thickness of the first inorganic layer 12, and the ordinate represents the bending stress value of the binding lines 82 in the bending area PA. From the simulation results in FIG. 10, it can be seen that the retained thickness of the first inorganic layer 12 ranges from 1000 angstroms to 5000 angstroms (i.e., 100 nm to 500 nm shown in FIG. 10). Although the stress on the binding lines 82 in the bending area PA increases, the range of increase is quite small. The risk of crack of the binding lines 82 is not increased basically, thereby ensuring the bending reliability of the bending area. Moreover, since the first inorganic layer 12 is arranged as a laminated structure, the thickness of the reserved first inorganic layer 12 tends to be thinned, which is conducive to adjusting the position of the stress center layer in the bending area PA on the premise of blocking water vapor, so as to reduce the risk of crack of the binding lines 82.

Furthermore, different from the above embodiments, a double-gate structure is used in the present embodiment. In addition, the bridge layer 40 also adopts a multi-layer bridge, and the electrically conductive electrode layer 30 adopts a laminated structure.

Specifically, the gate layer 60 includes a first gate layer 60-1 and a second gate layer 60-2. Accordingly, the gate insulating layer 22 also includes a first gate insulating layer 22-1 and a second gate insulating layer 22-2. The first gate insulating layer 22-1 is located between the semiconductor layer 50 and the first gate layer 60-1. The second gate insulating layer 22-2 is located between the first gate layer 60-1 and the second gate layer 60-2. The first gate layer 60-1 forms first gates 61-1 of the first thin film transistor T1 and the second thin film transistor T2 in the display area AA, and also forms corresponding gate scanning lines 63. The first gate layer 60-1 forms first signal transfer lines 62 in the bending area PA. The second gate layer 60-2 forms second gates 61-2 of the first thin film transistor T1 and the second thin film transistor T2 in the display area AA. Certainly, the second gate layer 60-2 may also form other signal lines in the display area AA and corresponding other signal transfer lines in the bending area PA.

Further, the bridge layer 40 is arranged as a multi-layer, so that the stress center layer of the bending area PA can be effectively adjusted. The bridge layer 40 includes a first bridge layer 40-1 and a second bridge layer 40-2. If the first bridge layer 40-1 is disposed on the second planarization layer 92, then there is further a requirement for a fourth planarization layer 95 correspondingly. The fourth planarization layer 95 covers on the first bridge layer 40-1 and the second planarization layer 92. The second bridge layer 40-2 is disposed on the fourth planarization layer 95. The third planarization layer 93 covers on the second bridging layer 40-2 and the fourth planarization layer 95. The first bridging layer 40-1 forms a first bridge electrode 41 in the function area FA and a second bridge electrode 42 in the display area AA. The second bridging layer 40-2 forms a third bridge electrode 43 in the function area FA and a fourth bridge electrode 44 in the display area AA. The first bridge electrode 41 extends from the function area FA to the display area AA and is connected with the second source 81 of the first thin film transistor T1. The third bridge electrode 43 is connected with the first bridge electrode 41. The second bridge electrode 42 is connected with the second source 81 of the second thin film transistor T2, and the fourth bridge electrode 44 is connected with the second bridge electrode 42.

Further, the electrically conductive electrode layer 30 is disposed on the third planarization layer 93. The electrically conductive electrode layer 30 includes a first electrically conductive electrode layer 30-1 and a second electrically conductive electrode layer 30-2. The first electrically conductive electrode layer 30-1 forms a first auxiliary electrode 33 in the function area FA and a second auxiliary electrode 34 in the display area AA. The first auxiliary electrode 33 is connected with the third bridge electrode 43, and the second auxiliary electrode 34 is connected with the fourth bridge electrode 44. The second electrically conductive electrode layer 30-2 forms a first pixel electrode 31 in the function area FA and a second pixel electrode 32 in the display area AA. The first pixel electrode 31 is connected with the first auxiliary electrode 33, and the second pixel electrode 32 is connected with the second auxiliary electrode 34. The other descriptions may refer to the above embodiments, and are not redundantly repeated herein.

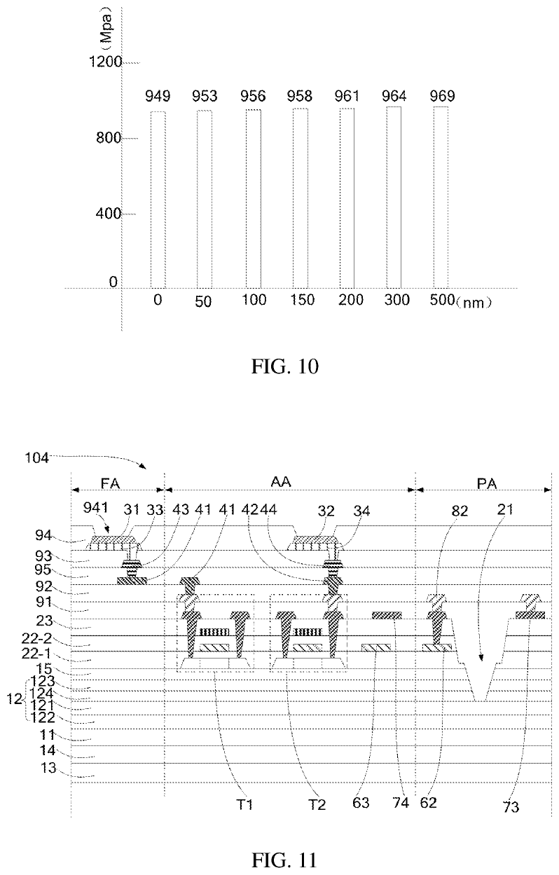

In one embodiment, reference is made to FIG. 11. FIG. 11 is a fifth section view of a schematic structural diagram of the display panel disclosed in the embodiments of the present disclosure. Different from the above embodiments, in the display panel 104 of the present embodiment, the first inorganic layer 12 includes a first silicon oxide layer 122, a first silicon nitride layer 121, a second silicon oxide layer 124, and a second silicon nitride layer 123 which are stacked on the first transparent substrate 11. The first via hole 21 penetrates through the second silicon nitride layer 123 and the second silicon oxide layer 124 to expose the first silicon nitride layer 121.

Optionally, the thickness of the first silicon oxide layer 122 is smaller than the thickness of the second silicon oxide layer 124. The thickness of the first silicon oxide layer 122 ranges from 100 angstroms to 1000 angstroms. The thickness of the first silicon nitride layer 121 ranges from 500 angstroms to 2000 angstroms. The thickness of the first silicon oxide layer 122 ranges from 2000 angstroms to 6000 angstroms. The thickness of the second silicon nitride layer 123 ranges from 500 angstroms to 2000 angstroms. The thickness of the first inorganic layer 12 exposed by the first via hole 21 is controlled between 1000 angstroms and 5000 angstroms.

It can be understood that since the barrier effect against water vapor of the silicon oxide is worse than that of the silicon nitride, the first inorganic layer 12 retained in the bending area PA includes the first silicon oxide layer 122 and the first silicon nitride layer 121 as much as possible. Moreover, in order to reduce the thickness of the retained first inorganic layer 12, the first silicon oxide layer 122 may have small thickness. On the premise of meeting the interface adhesion with the first transparent substrate 11, the thickness of the retained first inorganic layer 12 is reduced as much as possible. The second silicon oxide layer 124 may be penetrated by the first via hole 21. That is, the second silicon oxide layer 124 may be completely etched in the area corresponding to the first via hole 21, and the stress matching between silicon oxide and organic substrate material can be effectively adjusted. Accordingly, the second silicon oxide layer 124 may have large thickness. The other descriptions may refer to the above embodiments, and are not redundantly repeated herein.

In one embodiment, reference is made to FIG. 12. FIG. 12 is a sixth section view of a schematic structural diagram of the display panel disclosed in the embodiments of the present disclosure. Different from the above embodiments, in the display panel 105 of the present embodiment, a plurality of second protrusions 1211 are disposed on the surface of the first inorganic layer 12 exposed by the first via hole 21. The first inorganic layer 12 exposed by the first via hole 21 includes the first silicon nitride layer 121 and the first silicon oxide layer 122, wherein a plurality of second protrusions 1211 are disposed on the first silicon nitride layer 121. The second protrusions 1211 can extend the diffusion and infiltration path of water vapor and reduce the stress expansion caused by the thermal stress of the first transparent substrate 11 in the area of the first via hole 21, so as to achieve the purpose of releasing water vapor and stress. In this way, the problem of the occurrence of mura in the display area AA close to the bending area PA can be further improved. Optionally, the cross-sectional shape of the second protrusion 1211 also includes square, trapezoid, triangle, etc. The other descriptions may refer to the above embodiments, and are not redundantly repeated herein.

Moreover, it should be explained that, in order to realize the display function of the display panel, the display panel of the present disclosure further includes a light-emitting function layer disposed on the pixel definition layer 94. In addition, in order to protect the light-emitting function layer, the display panel of the present disclosure further includes a packaging layer disposed on the light-emitting function layer. The display panel 105 in the aforementioned embodiment is described below as an example.

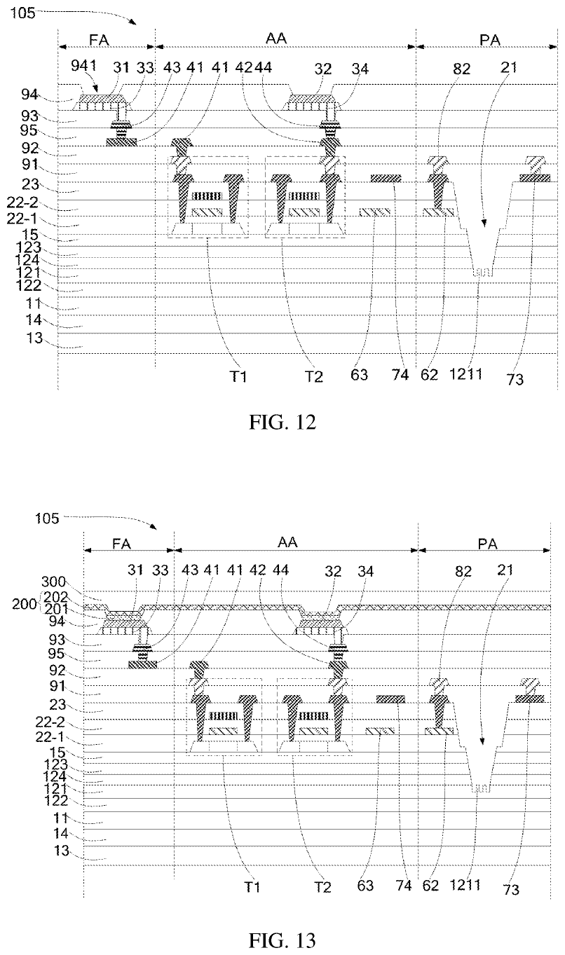

Specifically, reference is made to FIG. 13. FIG. 13 is a partial detailed structural diagram of the display panel disclosed in the present disclosure. The light-emitting functional layer 200 includes a light-emitting unit 201 and a cathode 202. The light-emitting unit 201 is formed of light-emitting materials printed in the pixel opening of the pixel definition layer 94. The light-emitting materials of different colors form the light-emitting units of different colors, and the light-emitting units of different colors emit light of different colors, so as to realize the color display of the display panel. For example, the light-emitting unit 201 may include a red light-emitting unit formed of a red light-emitting material, a green light-emitting unit formed of a green light-emitting material, and a blue light-emitting unit formed of a blue light-emitting material. The red light-emitting unit emits red light, the green light-emitting unit emits green light, and the blue light-emitting unit emits blue light.

The cathode 202 covers on the light-emitting unit 201 and the pixel definition layer 94. The light-emitting unit 201 emits light under the cooperative action of the corresponding pixel electrode (e.g., the first pixel electrode 31 or the second pixel electrode 32) and the cathode 202.

Optionally, the light-emitting function layer 200 may further include a hole injection layer (HIL) and a hole transport layer (HTL) disposed between the light-emitting unit 201 and the pixel electrode, and an electron injection layer (EIL) and an electron transport layer (ETL) disposed between the light-emitting unit 201 and the cathode 202. The hole injection layer receives the holes transmitted by the pixel electrode, and the holes are transmitted to the light-emitting unit 201 through the hole transport layer. The electron injection layer receives the electrons transmitted by the cathode 202, and the electrons are transmitted to the light-emitting unit 201 through the electron transport layer. The holes and electrons are combined in the light-emitting unit 201 to generate excitons, which transition from the excited state to the ground state to release energy and emit light.

The packaging layer 300 covers the light-emitting function layer 200 to protect the light-emitting unit 201 of the light-emitting function layer 200 and to avoid of the intrusion of water vapor, which leads to the failure of the light-emitting unit 201. Optionally, the packaging layer 300 may be encapsulated by thin films. For example, the packaging layer 300 may be a laminated structure formed by successively stacking three films of the first inorganic packaging layer, the organic packaging layer, and the second inorganic packaging layer, or a laminated structure of more layers.

Certainly, the display panel 105 of the present disclosure may further include a touch electrode layer, a polarizer, a cover plate, and other structures disposed on one side of the packaging layer 300 away from the light-emitting function layer 200, and the further description is not redundantly repeated herein.

An electronic device is further disclosed in the embodiments of the present disclosure. The electronic device includes the display panel in one of the foregoing embodiments. The electronic device includes electronic devices such as mobile phone, tablet, television.

### According to the Aforementioned Embodiments

A display panel and an electronic device are disclosed in the present disclosure. The display panel includes the display area and the bending area located in one side of the display area. The display panel further includes the first transparent substrate, the first inorganic layer located on one side of the first transparent substrate, and the second inorganic layer located on one side of the first inorganic layer away from the first transparent substrate. A first via hole is defined in the second inorganic layer in the bending area. The first via hole penetrates the second inorganic layer and part of the first inorganic layer, so that an area of the first inorganic layer corresponding to the first via hole retain a certain thickness of whole film layer to protect the first transparent substrate and avoid the influences of water vapor and the etching process of the first via hole on the first transparent substrate. Accordingly, the problem that mura occurs near the bending area due to the exposed first transparent substrate is avoided, and thus the problem of local mura occurring in the position near the bending area in the existing display panel is solved.

In the aforementioned embodiments, the description of each embodiment has its own emphasis. The part not detailed in one embodiment may refer to the related description of other embodiments.

The embodiments of the present disclosure are described in detail above. Specific examples are used in this text for illustrating the principles and implementations of the present disclosure. The description of the aforementioned embodiments is merely intended to help understand the methods of the present disclosure and a concept thereof. It can be understood that for those skilled in the art, equivalent substitutions or changes can be made according to the technical scheme of the present disclosure and its inventive concept, and all these substitutions or changes should belong to the protection scope of the claims attached to the present disclosure.

What is claimed is:

1. A display panel comprising a display area and a bending area located in one side of the display area, wherein the display panel further comprises:
a first transparent substrate;
a first inorganic layer located on one side of the first transparent substrate;
a semiconductor layer disposed on one side of the first inorganic layer away from the first transparent substrate; and
a second inorganic layer covering on the semiconductor layer and the first inorganic layer;
wherein a first via hole is defined in the second inorganic layer in the bending area, and the first via hole penetrates the second inorganic layer and part of the first inorganic layer.

2. The display panel according to claim 1, wherein the first inorganic layer comprises at least one silicon oxide layer and at least one silicon nitride layer.

3. The display panel according to claim 2, wherein the first inorganic layer comprises a first silicon nitride layer covering on the first transparent substrate and a first silicon oxide layer covering one side of the first silicon nitride layer away from the first transparent substrate, and the first via hole penetrates part or all of the first silicon oxide layer to expose the first silicon nitride layer.

4. The display panel according to claim 3, wherein the first inorganic layer further comprises a second silicon nitride layer covering one side of the first silicon oxide layer away from the first silicon nitride layer, and the first via hole further penetrates the second silicon nitride layer.

5. The display panel according to claim 2, wherein the first inorganic layer comprises a first silicon oxide layer, a first silicon nitride layer, a second silicon oxide layer, and a second silicon nitride layer which are stacked on the first transparent substrate in order, and the first via hole penetrates the second silicon nitride layer and the second silicon oxide layer to expose the first silicon nitride layer.

6. The display panel according to claim 5, wherein a thickness of the first silicon oxide layer is smaller than a thickness of the second silicon oxide layer.

7. The display panel according to claim 1, wherein the first transparent substrate is provided with a plurality of first protrusions in an area corresponding to the first via hole.

8. The display panel according to claim 1, wherein a surface of the first inorganic layer exposed by the first via hole is provided with a plurality of second protrusions.

9. The display panel according to claim 1, wherein a thickness of the first inorganic layer exposed by the first via hole ranges from 1000 angstroms to 5000 angstroms.

10. The display panel according to claim 1, wherein the display panel further comprises a function area disposed adjacent to the display area and a first thin film transistor and a second thin film transistor which are disposed in the display area, and the first thin film transistor is disposed close to the function area, wherein the display panel further comprises:
An electrically conductive electrode layer disposed on one side of the first thin film transistor and the second thin film transistor away from the first transparent substrate, wherein a first pixel electrode is formed in the function area, a second pixel electrode is formed in the display area, the first pixel electrode is connected with the first thin film transistor, and the second pixel electrode is connected with the second thin film transistor.

11. The display panel according to claim 10, wherein a bridge layer is further disposed between the first thin film transistor and the electrically conductive electrode layer, the bridge layer forms a first bridge electrode in the function area and a second bridge electrode in the display area, the first pixel electrode is connected with the first thin film transistor through the first bridge electrode, and the second pixel electrode is connected with the second thin film transistor through the second bridge electrode.

12. The display panel according to claim 11, wherein the second inorganic layer comprises a gate insulating layer and an interlayer insulating layer which are stacked in order, and the gate insulating layer is disposed to face the semiconductor layer, the semiconductor layer forms a channel region of the first thin film transistor and a channel region of the second thin film transistor and a source region and a drain region located on both sides of the channel region in the display area, and the gate insulating layer covers on the semiconductor layer and the first inorganic layer, wherein the display panel further comprises:
a gate layer disposed on the gate insulating layer, wherein the gate layer forms a gate of the first thin film transistor and a gate of the second thin film transistor in the display area, and forms a first signal transfer line in the bending area, wherein the interlayer insulating layer covers on the gate layer and the gate insulating layer, the interlayer insulating layer is patterned to form the first via hole, and to form a second via hole in the display area;
a first source/drain layer disposed on the interlayer insulating layer, wherein the first source/drain layer forms a first source and a first drain of the first thin film transistor and a first source and a first drain of the second thin film transistor in the display area, and forms a second signal transfer line in the bending area;
a first planarization layer covering on the first source/drain layer and the interlayer insulating layer, and filling the first via hole;
a second source/drain layer disposed on the first planarization layer, wherein the second source/drain layer forms a second source of the first thin film transistor and a second source of the second thin film transistor in the display area, and forms a plurality of binding lines in the bending area;
a second planarization layer covering on the second source/drain layer and the first planarization layer, wherein the bridge layer is disposed on the second planarization layer;
a third planarization layer covering on the bridge layer and the second planarization layer, wherein the electrically conductive electrode layer is disposed on the third planarization layer;
wherein the gate is disposed corresponding to the channel region, the first source is connected with the source region, the first drain is connected with the drain region, the second source is connected with the first drain, the first bridge electrode and the second bridge electrode are respectively connected with the corresponding second source, the first signal transfer line is connected with the second signal transfer line, and the binding lines are connected with the second signal transfer line.

13. An electronic device comprising a display panel which comprises a display area and a bending area located in one side of the display area, wherein the display panel further comprises:
a first transparent substrate;
a first inorganic layer located on one side of the first transparent substrate;
a semiconductor layer disposed on one side of the first inorganic layer away from the first transparent substrate; and
a second inorganic layer covering on the semiconductor layer and the first inorganic layer;
wherein a first via hole is defined in the second inorganic layer in the bending area, and the first via hole penetrates the second inorganic layer and part of the first inorganic layer.

14. The electronic device according to claim 13, wherein the first inorganic layer comprises at least one silicon oxide layer and at least one silicon nitride layer.

15. The electronic device according to claim 14, wherein the first inorganic layer comprises a first silicon nitride layer covering on the first transparent substrate and a first silicon oxide layer covering one side of the first silicon nitride layer away from the first transparent substrate, and the first via hole penetrates part or all of the first silicon oxide layer to expose the first silicon nitride layer.

16. The electronic device according to claim 15, wherein the first inorganic layer further comprises a second silicon nitride layer covering one side of the first silicon oxide layer away from the first silicon nitride layer, and the first via hole further penetrates the second silicon nitride layer.

17. The electronic device according to claim 14, wherein the first inorganic layer comprises a first silicon oxide layer, a first silicon nitride layer, a second silicon oxide layer, and a second silicon nitride layer which are stacked on the first transparent substrate in order, and the first via hole penetrates the second silicon nitride layer and the second silicon oxide layer to expose the first silicon nitride layer.

18. The electronic device according to claim 17, wherein a thickness of the first silicon oxide layer is smaller than a thickness of the second silicon oxide layer.

19. The electronic device according to claim 13, wherein the first transparent substrate is provided with a plurality of first protrusions in an area corresponding to the first via hole.

20. The electronic device according to claim 13, wherein a thickness of the first inorganic layer exposed by the first via hole ranges from 1000 angstroms to 5000 angstroms.
